(19) United States
(12) Patent Application Publication
(10) Pub. No.: US 2026/0293016 A1
(43) Pub. Date: Sep. 24, 2026

(54) PRODUCT WITH AUTOMATICALLY ASSEMBLABLE PARTS

(71) Applicant: Siemens Aktiengesellschaft, 80333 München (DE)

(72) Inventors: ALEXANDER DATHE, Neukirchen (DE); JAN MEHLICH, Chemnitz (DE)

(73) Assignee: Siemens Aktiengesellschaft, 80333 München (DE)

(21) Appl. No.: 19/475,928

(22) PCT Filed: Mar. 11, 2024
(86) PCT No.: PCT/EP2024/056332

§ 371 Date: Oct. 16, 2025

(30) Foreign Application Priority Data
Apr. 17, 2023 (EP) 23168241.0

(51) Int. Cl. H05K 5/15; F16B 5/06; H05K 7/20

(52) U.S. Cl. CPC H05K 5/15; F16B 5/0664; H05K 7/2089; F16B 2200/30

(57) ABSTRACT

A product includes a first part with projections having latching hooks, and a second part with receptacles and latching lugs in a region of the receptacles. The first and second parts are latched as the projections of the first part are inserted into the receptacles of the second part, and when fully inserted into the receptacles, the latching hooks and the latching lugs form latching connections. When beginning to insert Into the receptacles, the projections have a clearance in the receptacles in a first transverse direction and a second transverse direction orthogonal to the first transverse direction. The clearance starts from an initial value greater than zero and gradually decreases to zero, as the projections are inserted into the receptacles. The projections and receptacles have a contour of symmetrical trapezoids with a long side and a short side, with the long and short sides running in the first transverse direction.

The present invention relates to a (multi-part) product,
wherein the product has a first and a second part which are connected to each other by latching together,
wherein the first part has a first base body from which a number of projections extend so that the projections define an insertion direction,
wherein the second part has a second base body in which a number of receptacles are arranged,
wherein, when the first part is latched with the second part, one of the projections of the first part is inserted in the insertion direction into one of the receptacles of the second part,
wherein latching hooks are arranged on the projections and latching lugs are arranged on the second part in the region of the receptacles,
wherein, when the projections are fully inserted into the receptacles, the latching hooks and the latching lugs respectively form a latching connection,
wherein the projections and the receptacles are coordinated such that, at the beginning of the Insertion of the projections into the receptacles, the projections have a clearance in the receptacles, when viewed in a transverse plane orthogonal to the insertion direction, both in a first transverse direction and in a second transverse direction orthogonal to the first transverse direction, said clearance, when the projections are inserted into the receptacles, starting from an Initial value greater than zero, gradually decreases to zero.

The insertion direction is a direction with a sign. The projections are inserted into the receptacles in the insertion direction, and any release of the projections from the receptacles is performed in the opposite direction to the insertion direction.

The latching connections are therefore designed in such a manner that they can also simultaneously guide, position, and center the first part relative to the second part.

Such products are known. U.S. Pat. No. 11,287,097 B1 can be cited purely by way of example.

DE 10 2006 061 703 A1 discloses a product comprising a first and a second part which are connected to each other by means of latching together. The first part has a first base body from which a number of projections extend, so that the projections define an insertion direction. The second part has a second base body in which a number of receptacles are arranged. In the latched state, one of the projections of the first part is inserted in the insertion direction into one of the receptacles of the second part, and latching hooks are arranged on the projections and latching lugs are arranged on the second part in the region of the receptacles. Furthermore, the latching hooks and latching lugs respectively form a latching connection when latched together.

U.S. Pat. No. 10,857,954 B1 and EP 3 112 220 A1 essentially contain the same disclosure.

In manufacturing technology, there is a growing trend toward automating assembly processes, for example, using robots. For automated assembly, special attention must be paid to the joining of parts. Humans are usually superior to machines, especially when it comes to delicate assembly tasks. This is because humans can perform precise positioning well based on visual perception and, in some cases, tactile sensitivity. The machine, on the other hand, whether it is a robot or another machine, merely executes its preprogrammed movements, whereby the machine cannot detect whether the first part and/or the second part are positioned in exactly the right place. It is therefore necessary to design the parts of the product in such a manner that the individual parts of the product center themselves automatically during assembly with the aid of guides, insertion ramps, and other positioning aids.

The object of the present invention is to create possibilities by means of which such automatic centering in both transverse directions can be combined in a simple manner with a latching mechanism, so that the respective positioning aid also provides a latching connection.

The object is achieved by a product having the features of claim 1. Advantageous embodiments of the product are the subject matter of the dependent claims 2 to 8.

According to the invention, a product of the type mentioned above is designed such that, when viewed in the transverse plane, the projections and receptacles have the contour of symmetrical trapezoids with a respective long side and a respective short side, and such that the long and short sides run in the first transverse direction.

This design therefore essentially represents a dovetail that tapers in the direction of insertion.

The projections extend over a length when viewed in the insertion direction. Preferably, the projections and the receptacles are matched to each other in such a manner that, when inserting the projections into the receptacles, the clearance essentially assumes the value zero over the entire length of the projections simultaneously. With this design, when the projections are fully inserted into the receptacles, they lie flat against the inner sides of the receptacles over a large area. This results in a very stable attachment of the first part to the second part (or vice versa).

Preferably, the receptacles are open or thinner-walled in the region of the short sides of the trapezoids than in the region of the long sides of the trapezoids. This allows the installation height of the receptacles in the second transverse direction to be kept as low as possible.

The latching hooks are preferably arranged in the region of the long sides of the trapezoids. This solution is particularly easy to implement in terms of design.

Preferably, when the first and second part are detached from each other, the latching hooks are arranged within the volumes enclosed by the trapezoids and furthermore the latching lugs are arranged in a spring-elastic manner on the second base body. This feature reduces the installation height of the receptacles in the second transverse direction.

Preferably, the first part has recesses in transition regions from the projections to the first base body, over which the latching hooks and/or latching lugs can be bent, thereby releasing the respective latching connection. This makes it easier to release the latching connections. For example, a screwdriver can be applied in a simple manner using the recesses.

Preferably, the first part is the housing of an electronic assembly and the second part is a front cover of the electronic assembly. This situation represents a particularly common application of the present invention. This is especially true when a heat sink for cooling electronic power components is arranged in the housing.

The above-described properties, features, and advantages of this invention, as well as the manner in which they are achieved, will become clearer and more understandable in connection with the following description of the embodiments, which are explained in more detail in conjunction with the drawings. The drawings illustrate in a schematic view:

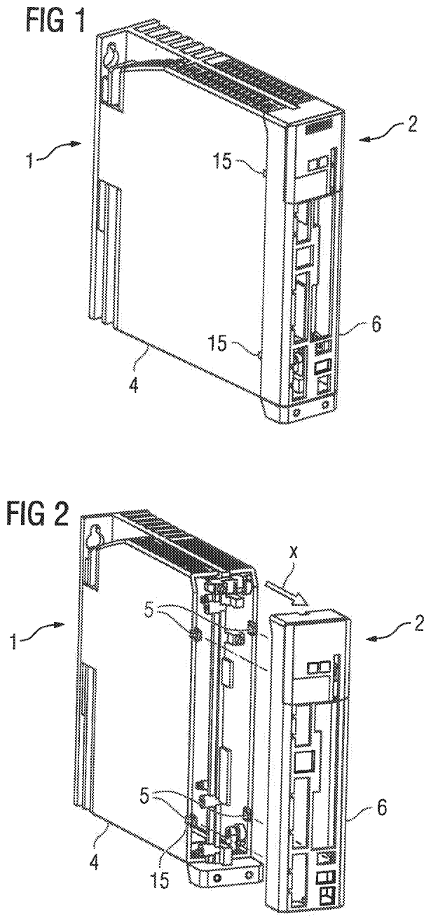

FIG. 1 a perspective view of an electronic assembly in a mounted state,

FIG. 2 the assembly from FIG. 1 prior to connection,

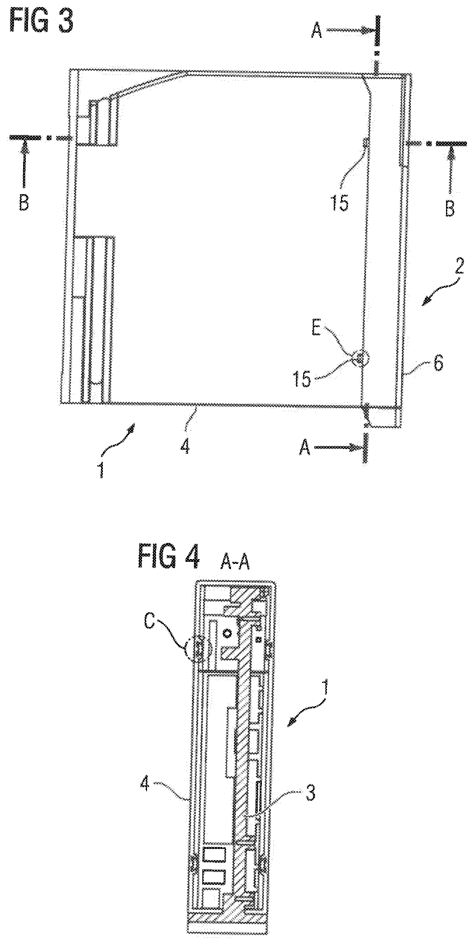

FIG. 3 the assembly from FIG. 1 from the side,

FIG. 4 a sectional view through the assembly from FIG. 1 along a line A-A in FIG. 3,

FIG. 5 a sectional view through the assembly from FIG. 1 along a line B-B in FIG. 3,

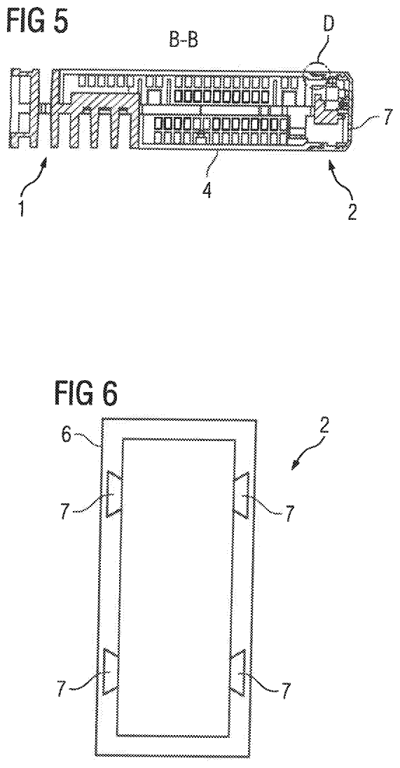

FIG. 6 an enlarged and not-to-scale view of a second base part when viewed from the direction A-A in FIG. 3,

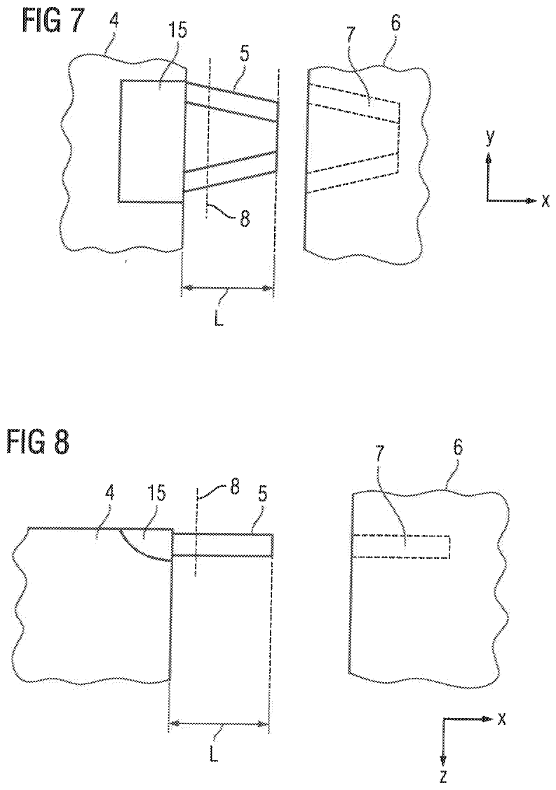

FIG. 7 a first base part and a second base part in the region of a projection and a receptacle when viewed from the first transverse direction.

FIG. 8 the first and the second base part from FIG. 7 when viewed from the second transverse direction,

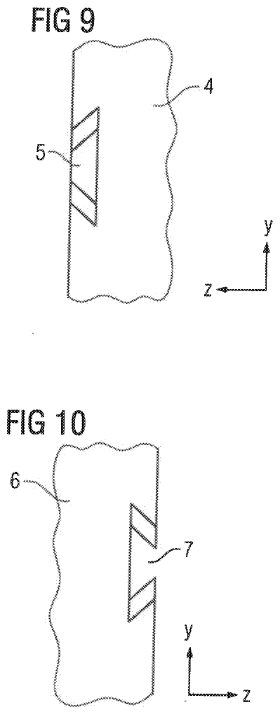

FIG. 9 a plan view of the first base part from FIG. 7 in the region of a projection when viewed in the opposite direction to an insertion direction,

FIG. 10 a plan view of the second base part from FIG. 7 when viewed in the insertion direction,

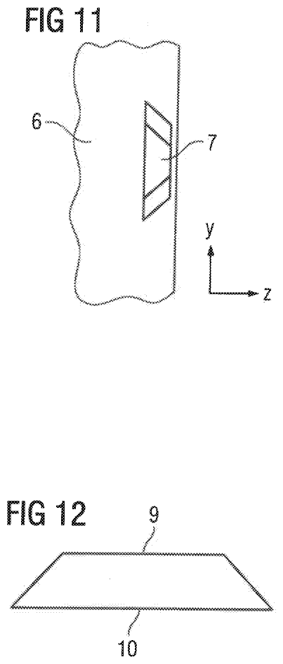

FIG. 11 a modification of the second base part shown in FIG. 10,

FIG. 12 a (conceptually infinitely thin) strip of the projection of the first base part from FIG. 7,

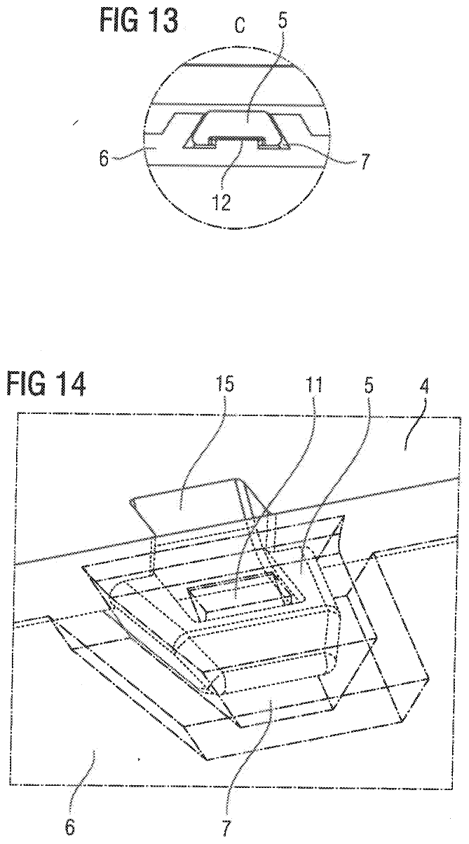

FIG. 13 a sectional view through a projection arranged in a receptacle,

FIG. 14 a perspective transparent representation of a first base part and a second base part in the region of a projection and a receptacle,

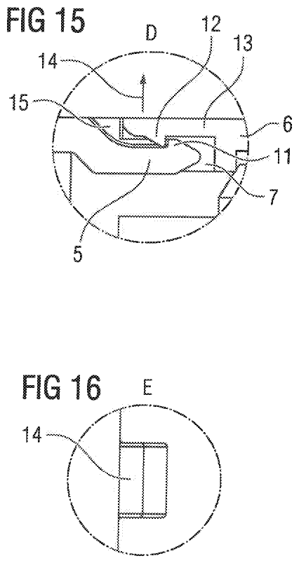

FIG. 15 a detail D in accordance with FIG. 5, and

FIG. 16 a detail E in accordance with FIG. 3.

The FIGS. 1 to 5 show different representations of the same product. The FIGS. 1 to 5 will therefore be explained together below. Reference will only be made to a single one of FIGS. 1 to 5 in individual cases if a respective detail is particularly clearly visible in that FIG,

In the example shown in FIGS. 1 to 5, the product is designed as an electronic assembly. The fact that the product is designed as an electronic assembly is purely illustrative. The product could also be designed in other ways, for example purely mechanically.

According to FIGS. 1 to 5, the product has a first part 1 and a second part 2. The first part 1 is, in this case, the housing of the electronic assembly, in which a heat sink 3 (FIG. 4) is arranged, which is used to cool electronic power components. The second part 2 is a front cover of the electronic assembly. However, other parts may also be involved. Furthermore, the product may comprise additional parts in addition to the first part 1 and the second part 2.

The first part 1 has a base body 4 from which-see in particular FIG. 2-a number of projections 5 extend. The base body 4 is hereinafter referred to as the first base body 4. The projections 5 thereby define an insertion direction x. The insertion direction x is the direction in which the projections 5 extend away from the first base body 4.

The second part 2 also has a base body 6, hereinafter referred to as the second base body 6. In accordance with FIG. 6, a number of receptacles are arranged in the second base body 6.

In order to connect the first and the second part 1, 2 to each other, the projections 5 are inserted into the receptacles 7 in the insertion direction x. There is one receptacle 7 for each projection 5. If necessary (for example, for reasons of compatibility with different types of first parts 1), there may be more receptacles 7 than projections 5. In this case, the surplus receptacles 7 are unused. When the projections 5 are fully inserted into the receptacles 7, the two parts 1, 2 latch together and are thus connected to each other.

Initially, the design of the projections 5 and the receptacles 7 is described below with regard to the insertion of the projections 5 into the receptacles 7. The latching arrangement is described later. Only an individual one of the projections 5 and the associated receptacle 7 is explained. Analog explanations apply for the other projections 5 and the corresponding receptacles 7. Furthermore, a coordinate system with the directions x, y and z is introduced. The coordinate system is a right Cartesian coordinate system. The direction x is, as already defined, the insertion direction x. The directions y and z are orthogonal to the direction of insertion x and also orthogonal to each other. They are referred to below as the first and second transverse direction y, z. The two transverse directions y and z refer to the respective projection 5 and the respective receptacle 7. They can therefore have different directions for a different projection 5 and a different receptacle 7. However, since the insertion direction x is uniform for all projections 5 and receptacles 7, the two transverse directions y and z always define the same transverse plane.

As a general principle, the projection 5 and the receptacle 7 are coordinated in such a manner:
that the projection 5 has a clearance in the receptacles 7 in both the first transverse direction x and the second transverse direction y at the start of insertion of the projection 5 into the receptacles 7,
that the clearance gradually decreases as the projection 5 is inserted into the receptacle 7, and
that the clearance reaches the value zero at the latest when the projection 5 is fully inserted into the receptacle 7.

The clearance thus gradually decreases from an initial value greater than zero in both transverse directions y and z to zero when inserting the projection 5 Into the receptacle 8.

The projection 5 extends over a length L in the insertion direction x (see FIGS. 7 and 8). Preferably, the projection 5 and the receptacle 8 are even matched to each other in such a manner that, when inserting the projection 5 into the receptacle 7, the clearance essentially assumes the value zero over the entire length L of the projection 5 simultaneously.

As shown in FIGS. 7 to 12, the projection 5 has the contour of a symmetrical trapezoid when viewed in the transverse plane defined by the two transverse directions y and z. The reference numeral 8 in FIGS. 7 and 8 denotes a line along which a (conceptually infinitely thin) strip is “cut out” of the projection 5. The strip is shown in FIG. 12. In particular, FIG. 12 shows the shape of the trapezoid particularly clearly. FIG. 13 shows the specific section for the specific design of the assembly shown in FIG. 1 to 5.

The trapezoid has a long side 8 and a short side 9. The long and short sides 8, 9 run in the first transverse direction y. However, due to the gradual tapering of the projection 5, the cross-section decreases further and further towards the front. The tapering can be linear in particular. The respective receptacle 7 is designed to match the associated projection 5.

By using the contour of a symmetrical trapezoid, it is possible for the receptacle 7 to be open in the region of the short side 9 of the trapezoid (FIG. 10) or at least to have thinner walls than in the region of the long side of the trapezoid (FIG. 11).

The design of the projections 5 and the receptacles 7 is now described below with regard to the projections 5 latching into the receptacles 7.

According to FIG. 2—see also FIG. 14—latching hooks 11 are arranged on the projections 5. Corresponding to this-see in particular FIG. 15—latching lugs 12 are arranged on the second part 2 in the region of the receptacles 7. When the projections 5 are fully inserted into the receptacles 7, the latching hooks 11 and the latching lugs 12 respectively form a latching connection. As shown in FIG. 14, the latching hooks 11 are arranged in the region of the long sides 10 of the trapezoids, namely within the volume enclosed by the trapezoids. In the specific design, this applies both when the first and second part 1, 2 are detached from each other and when the first and second parts 1, 2 are connected to each other. As a result, the corresponding arrangement of the latching hook 11 can also be seen in FIG. 13, because the latching lug 12 is visible there within the volume enclosed by the trapezoids. FIG. 15 also shows this fact.

According to FIG. 15, the latching lug 12 is arranged in a spring-elastic manner on the second base body 2. In particular, the latching lug 12 is connected to the second base body 6 via a relatively narrow web 13, so that the web 13 lifts slightly during the process of connecting the two parts 1, 2 to each other. The lifting is indicated in FIG. 15 by an arrow 14.

In order to release the respective latching connection, the first part 1 has a recess 15 in a transition region from the respective projection 5 to the first base body 4, see FIGS. 1 to 3, 7, 8, and 14 to 16. The recess 15 allows the respective latching hook 11 and/or the respective latching lug 12 to be bent over, thereby releasing the respective latching connection. In particular, a standard screwdriver can be used in the region of the recess 15.

In summary, the present invention thus relates to the following situation:

A product has a first and a second part 1, 2, which are connected to each other by latching together. The first part 1 has a first base body 4, from which a number of projections 5 extend, so that the projections 5 define an insertion direction x. The second part 2 has a second base body 6 in which a number of receptacles 7 are arranged, When the first part 1 is latched with the second part 2, one of the projections 5 of the first part 1 is inserted in the insertion direction x into one of the receptacles 7 of the second part 2. Latching hooks 11 are arranged on the projections 5, latching lugs 12 are arranged on the second part 2 in the region of the receptacles 7. When the projections 5 are fully inserted into the receptacles 7, the latching hooks 11 and the latching lugs 12 respectively form a latching connection. The projections 5 and the receptacles 7 are coordinated in such a manner that, at the beginning of the insertion of the projections 5 into the receptacles 7, the projections 5 have a clearance in the receptacles 7 in two mutually orthogonal transverse directions y, z, when viewed in a transverse plane orthogonal to the insertion direction x. The clearance gradually decreases to zero when inserting the projections 5 into the receptacles 7, starting from an initial value greater than zero. When viewed in the transverse plane, the projections 5 and the receptacles 7 have the contour of symmetrical trapezoids with a respective long side 10 and a respective short side 9. The long and short sides 10, 9 run in the first transverse direction y.

The present invention has many advantages. In particular, the projections 5 of the present invention, in cooperation with the receptacles 7, perform both a positioning aid and a guide as well as a holding and latching function. The fact that the projections 5 and the receptacles 7 perform all three tasks simultaneously results in a space-saving design that achieves precise component guidance during joining. The recesses 15 allow the latching connections to be quickly and easily released. The latching connections are virtually invisible when connected. Both the projections 5 and the receptacles 7 can be designed to be stable so that they do not deform during joining. Further latching connections or screw connections are not necessary.

Although the invention has been illustrated and described in detail by the preferred embodiment, the invention is not limited by the disclosed examples, and other variations can be derived from this by those skilled in the art without departing from the scope of protection of the invention.

1.-8. (canceled)

9. A product, comprising:
a first part comprising a first base body from which a number of projections extend so that the projections define an insertion direction, said projections having latching hooks arranged thereon; and
a second part comprising a second base body in which a number of receptacles are arranged, and having latching lugs arranged on the second part in a region of the receptacles, the first and second parts being connected together by latching such that when the first part is latched with the second part, the projections of the first part are inserted in the insertion direction into the receptacles of the second part in one-to-one correspondence, and when the projections are fully inserted into the receptacles, the latching hooks and the latching lugs form latching connections,
wherein the projections and the receptacles are coordinated such that, when the projections begin to insert into the receptacles, the projections have a clearance in the receptacles, when viewed in a transverse plane orthogonal to the insertion direction, both in a first transverse direction and in a second transverse direction orthogonal to the first transverse direction, with the clearance starting from an Initial value greater than zero, gradually decreasing to zero, as the projections are inserted into the receptacles, and
wherein, when viewed in the transverse plane, the projections and receptacles have a contour of symmetrical trapezoids with a respective long side and a respective short side, with the long and short sides running in the first transverse direction.

10. The product of claim 9, wherein the projections extend over a length as viewed in the insertion direction, and wherein the projections and the receptacles are coordinated with each other in such a manner that, when inserting the projections into the receptacles, the clearance essentially assumes the value zero over an entire length of the projections simultaneously

11. The product of claim 9, wherein the receptacles are open in a region of the short sides of the trapezoids or are thinner-walled than in a region of the long sides of the trapezoids.

12. The product of claim 9, wherein the latching hooks are arranged in a region of the long sides of the trapezoids.

13. The product of claim 9, wherein, when the first and second parts are detached from each other, the locking hooks are arranged within volumes enclosed by the trapezoids and the latching lugs are arranged in a spring-elastic manner on the second base body.

14. The product of claim 9, wherein the first part comprises recesses in transition regions from the projections to the first base body, so as to enable a release of the latching connections when bending the latching hooks and/or the latching lugs via the recesses.

15. The product of claim 9, wherein the first part embodies a housing of an electronic assembly and the second part embodies a front cover of the electronic assembly.

16. The product of claim 15, further comprising a heat sink designed to cool electronic power components arranged in the housing.
